(19) United States
(12) Patent Application Publication
(10) Pub. No.: US 2008/0159133 A1
(43) Pub. Date: Jul. 3, 2008

(54) Method of providing wireless signal strength and congestion data of an access point

(76) Inventors: Ka Ki Yeung, Fremont, CA (US); Tiefeng Ye, Shanghai (CN)

Correspondence Address: O'KEEFE, EGAN, PETERMAN & ENDERS LLP, 1101 CAPITAL OF TEXAS HIGHWAY SOUTH, #C200, AUSTIN, TX, 78746, US

(21) Appl. No.: 11/645,877

(22) Filed: Dec. 27, 2006

(51) Int. Cl. G01R 31/08

(52) U.S. Cl. 370/230

(57) ABSTRACT

A technique for displaying both wireless signal strength information and congestion information related to the use of a wireless access point by a wireless node is provided. The technique may include the use of a graphical display. Further the technique may include the use a common icon to display both the signal strength and congestion information. The number of bars on the icon may indicate signal strength while some other graphical indicator of the icon, such as color may indicate congestion. Congestion may be based upon the number of other nodes utilizing the wireless access point and/or the amount of bandwidth utilized by other nodes connecting to the access point. A user utilize the presented information to make an informed selection of whether to connect to a particular access point based on the data provided. Signal strength may indicate the signal to noise ratio, and can be depicted with bars on a graphical illustration, while congestion data can be depicted by color, boldness, grey scale, cross-hatching or the like of the bars.

### TECHNICAL FIELD OF THE INVENTION

The techniques disclosed herein relate to a method and apparatus for providing signal strength and congestion information of an access point to a wireless user, and particularly to graphically displaying signal strength and congestion data in one display window for a user to make a more informed selection regarding use of the access point on the data provided.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Wireless networking provides a means for mobility, connectivity, and anywhere/anytime computing. Laptops and notebook computers are examples of typical computer systems that are configured for wireless networking. A standard laptop equipped with a wireless module is able to connect to 802.11 networks and an icon is typically shown on the laptop display indicating the signal strength of the wireless connection. The signal strength is usually an indication of the signal to noise ratio (SNR), and thus, an underlying factor in determining the transmission speeds, or more specifically, coding rates of the wireless signal. However, there are problems associated with merely using the SNR or coding rates to determine the desirability of the network connection.

One problem is that network congestion information is not decoupled from the SNR data. In prior art FIG. 1, a typical wireless environment 100 with nodes is shown. Nodes 102A, 102B and 102C are shown with signals 103 being sent and received between the nodes and an access point 104. The access point 104 may be any mechanism or node that provides wireless access for the other nodes to a network. For example, typical prior art access points may be a wireless 802.11 access point, a wireless router, or the like. Any given node may have sensing range within which if other nodes or access points are present the given node may detect the wireless signals of the other nodes and/or access points. For example a sensing range 106 for node 102A is shown. It will be recognized that the sensing range of any given node may be dependent upon both the hardware of that node and the transmission strength of the other nodes and access points. In addition, the sensing range may be impacted by factors such as the location of a node and access point in the physical environment surrounding such locations (for example walls, buildings, etc.).

FIGS. 2A-2C show a prior art signal strength display or icon such as typically shown with respect wireless network connections. In FIG. 2A, the signal strength display shows poor signal strength 200A. since the signal strength indicator 202 shows only the first bar 204 and second bar 205 on the signal strength indicator 202 are illuminated or activated, while the third bar 206 and fourth bar 208 are not. In FIG. 2B, the signal strength display shows a medium signal strength 200B. The first bar 204, second bar 205, and third bar 206 of the indicator 202 are illuminated or activated, while the fourth bar 208 is not. In FIG. 2C, the signal strength display shows an excellent signal strength 200C. The first bar 204, second bar 205, third bar 206 and fourth bar 208 are all illuminated or activated on the indicator 202.

However, even if a user (such as node 102A) is very close to the wireless access point 104 and has a corresponding strong signal strength indicator with regard to the connection between the node 102A and the access point 104, there still may be a number of other nodes with interfering wireless transmissions on the same channel thus causing the overall connectivity throughput to be low. Thus, for example the 802.11 standard is a Carrier Sense, Multiple Access (CSMA) standard wherein the underlying physical medium is a shared channel. Therefore, if there are many computers or nodes connecting to the access point or within the sensing range 106, the channel can be very congested. Also, if the other nodes (102B and 102C) are consuming high bandwidth (for example downloading large files), the congestion will be increased.

The quality of a connection between a node 102A and an access point 104 may also be affected by nodes outside of the sensing range 104 of the node 102A. FIG. 1 shows a hidden node 108 (i.e. hidden from node 102A, not necessarily the other nodes and the access point) outside of the receiving sensing range 106. Hidden node 108 receives and sends signals 109 to the access point 104. Even though node 102A is outside of the sensing range 106 of node 102A, hidden nodes 108 may still consume bandwidth of the access point 104 and thus still cause congestion that impacts the connection of node 102A to the access point 104.

The current art display 202 fails to indicate the congestion or overall throughput of the network. Neighboring nodes will interfere with the transmission of a given node and lower the network throughput for the given node even though signal strength is high, as in FIG. 2C, for example. The amount of bars 204, 205, 206, 208 displayed on a prior art indicator display 202 thus fails to reflect the affects of other nodes on a given nodes connection.

### SUMMARY OF THE INVENTION

A technique is disclosed herein for displaying both wireless signal strength information and congestion information related to the use of an access point by a first node. The technique may use a common icon to display both the signal strength and congestion information. The number of bars on the icon may indicate signal strength while some other graphical indicator of the icon may indicate congestion.

In one embodiment a method of providing signal strength information and congestion information related to use of an access point by a first node is described. The method may include detecting the usage of the access point wireless environment by other nodes in order to obtain congestion information related to the access point and detecting wireless network signal strength information at the first node. The method may further include displaying, at the first node, the signal strength information and the congestion information. A user may then be allowed to select an access point based on the information provided.

In another embodiment, a method of providing signal strength information and congestion information related to use of an access point by a first node is described. The method may include detecting an amount of other nodes connected to an access point in an area as part of determining a wireless network congestion level and determining the signal strength at the first node. The method may further include graphically displaying, at the first node, the signal strength and the congestion level. The signal strength data can be depicted with bars, and congestion data can be depicted with colored bars, or boldness of the bars on the graphical illustration.

In another embodiment, an information handling system having a wireless signal strength and congestion data display related to use of an access point is provided. The information handling system may comprise a wireless device within the information handling system configured to detect usage of the access point wireless environment by surrounding wireless nodes in order to obtain congestion information related to the access and to detect the wireless signal strength of the access point wireless environment. The information handling system may further comprise a display window within the information handling system, the information handling system configured to provide signal strength and congestion data in the display window.

As described below, other features and variations can be implemented, if desired, and a related systems and methods can be utilized, as well.

### DESCRIPTION OF THE DRAWINGS

It is noted that the appended drawings illustrate only exemplary embodiments of the invention and are, therefore, not to be considered limiting of its scope, for the invention may admit to other equally effective embodiments.

FIG. 1 is a prior art block diagram of a typical wireless environment having nodes;

FIG. 2A is a prior art diagram of a signal strength display showing a poor signal strength;

FIG. 2B is a prior art diagram of a signal strength display showing an average or medium signal strength;

FIG. 2C is a prior art diagram of a signal strength display showing an excellent signal strength;

FIG. 3A is a diagram of a signal strength and congestion display showing excellent signal strength and minimal congestion;

FIG. 3B is a diagram of a signal strength and congestion display showing excellent signal strength and average congestion;

FIG. 3C is a diagram of a signal strength and congestion display showing excellent signal strength and high congestion;

FIG. 3D is a diagram of a signal strength and congestion display showing poor signal strength and minimal congestion;

FIG. 3E is a diagram of a signal strength and congestion display showing poor signal strength and average congestion;

FIG. 3F is a diagram of a signal strength and congestion display showing poor signal strength and high congestion; and

FIG. 4 is a prior art block diagram of an IEEE 802.11 MAC RTS/CTS transmission.

### DETAILED DESCRIPTION OF THE INVENTION

For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a personal computer, a server computer system, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, and a video display. The information handling system may also include one or more buses operable to transmit communications between the various hardware components.

The present disclosure provides systems and methods for displaying both wireless signal strength information and congestion information related to the use of an access point by a first node. In one embodiment, the technique may use a common icon to display both the signal strength and congestion information. In a further embodiment, the number of bars on the icon may indicate signal strength while some other graphical indicator of the icon may indicate congestion.

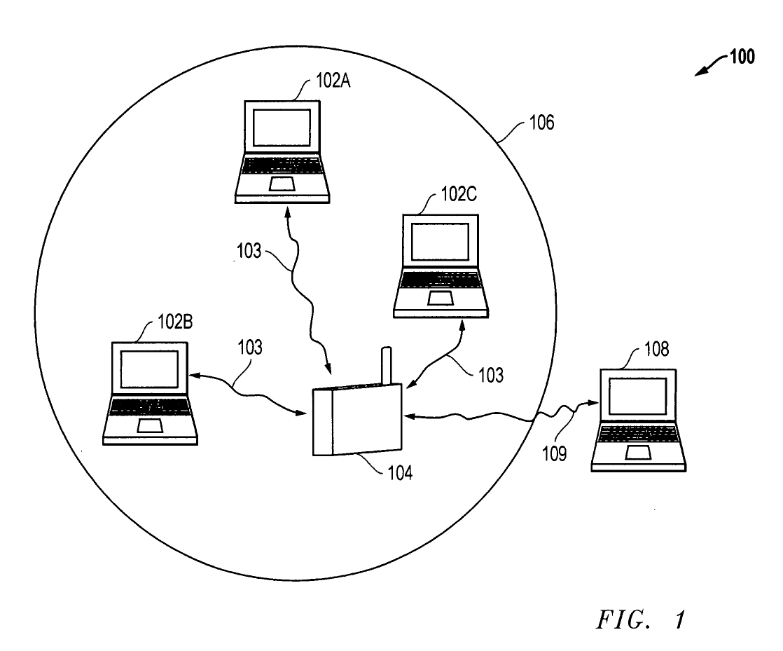

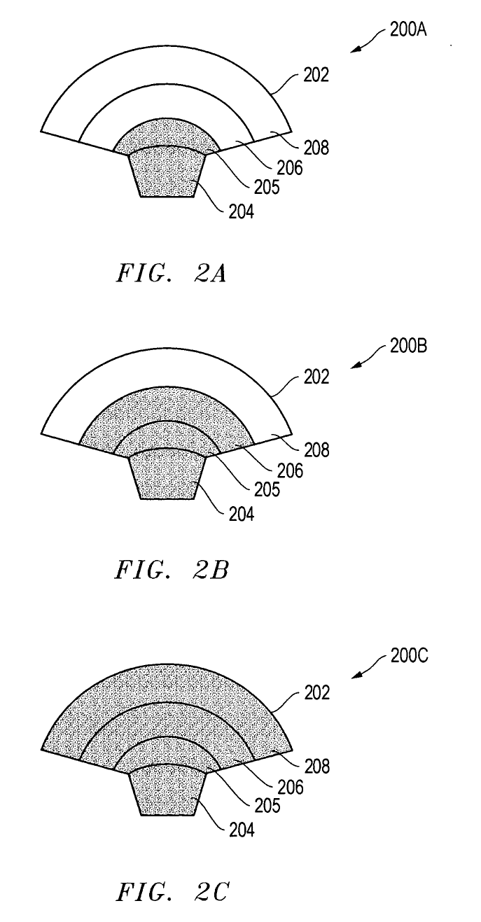

As shown with respect to prior art FIGS. 1, and 2A-2C, the typical wireless network quality indicator merely displays a signal strength indicator. The signal strength indicator merely detects signal strength and not congestion. As seen in FIG. 2C, the signal strength indicator 202 could display excellent signal strength, while congestion causes interference resulting in poor connectivity characteristics for a user. In FIG. 1, for example, congestion could be caused by the numbers of adjacent nodes within the receiving sensing range, the bandwidth of the access point consumed by other nodes, including hidden nodes outside of receiving sensing range that are communicating with the access point. The techniques of the present disclosure provide for the decoupling of congestion data so that the user is provided more detailed feedback regarding the wireless environment.

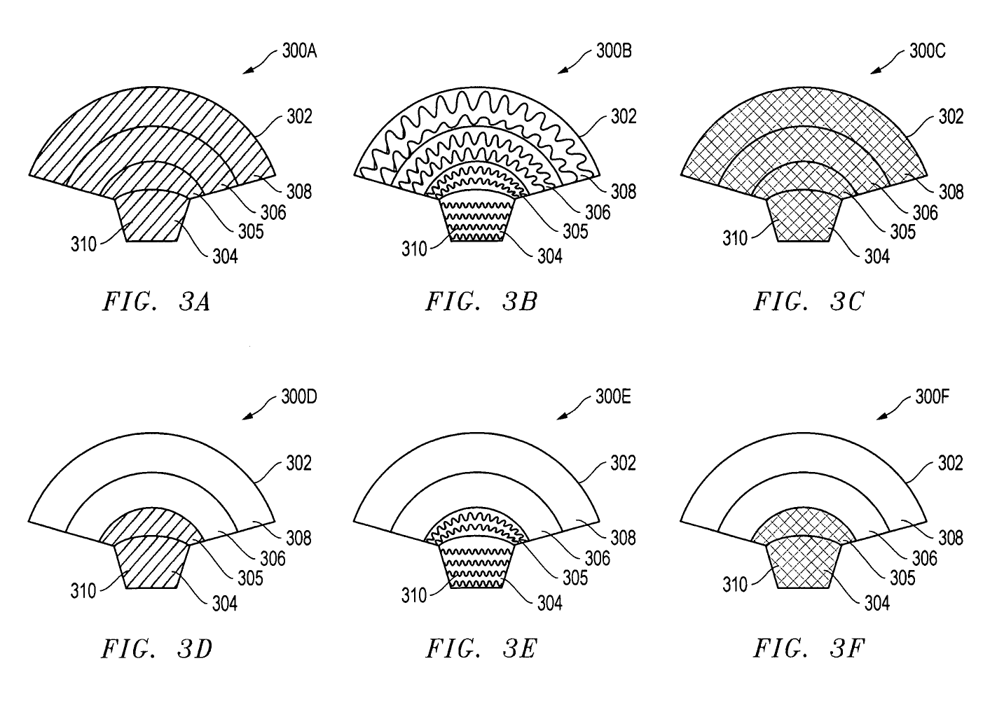

The techniques described herein provide a mechanism for separating congestion information from the wireless link strength indication thus given a user more feedback as to the true wireless environment and provided the user more details to make informed decisions regarding the selection of wireless access points. One exemplary embodiment of such techniques are shown in FIGS. 3A-3F, which show the signal strength and congestion display with various levels of signal strength and congestion. As shown in FIGS. 3A-3F, the number of bars displayed may be used to indicate signal strength (similar to prior art techniques), however, another graphical indicator may be used to show the wireless traffic congestion levels. In one embodiment, the other graphical indicator may be the color of the bars. In FIG. 3A, the signal strength and congestion display shows a detected condition 300A that indicates excellent signal strength and minimal congestion. Usage of an access point by other nodes is detected in order to obtain congestion information related to the access point. In one embodiment, usage by other numbers may include the amount of other nodes connecting to the access point and/or the amount of bandwidth utilized by other nodes connecting to the access point. It will be recognized that the congestion determination may be determined based upon other factors and the number of nodes using an access point and/or the bandwidth consumed by the other numbers are just exemplary factors that may indicate the congestion impacting a wireless network connection.

Thus as shown in FIG. 3A, signal strength at the first node is determined and displayed along with congestion information in a graphical illustration. A user can select an access point based on the signal strength and congestion information provided. As shown in FIGS. 3A-3F, the signal strength information and congestion information can be displayed in a graphical illustration. Signal strength information is displayed via bars 304, 305, 306, and 308 on the graphical illustration of the signal strength and congestion indicator 302. Congestion information is displayed on the graphical illustration via a congestion indicator 310 which may be displayed via varying the color of the bars, the boldness of the bars, the shades of grey scale of the bars, the cross-hatching of the bars, or the like. FIGS. 3A and 3D both show minimal congestion, depicted with diagonal cross-hatching via the congestion indicator 310. FIGS. 3B and 3E both show average congestion, depicted with wavy line cross-hatching via the congestion indicator 310. FIGS. 3C and 3F both show high congestion, depicted with “X” cross-hatching via the congestion indicator 310. In one embodiment, the variations in color of the bars indicate the congestions (for example green or minimal congestion, yellow or average congestion and red or high congestion). For illustration purposes in the black and white figures, these color variations are indicated by the use of different cross-hatching of the bars. It will be recognized that any type of visual indication of the congestion as described above may be utilized and the techniques described herein are not limited to any particular indicator. Further, it will be recognized that the techniques described herein are not limited to the illustrative example of three levels of congestion. Thus, more or less different levels of congestion may be displayed to the user. In one example five levels of congestion such as poor, below average, average, above average, and excellent may be utilized.

As illustrated in the figures, FIG. 3A shows excellent signal strength, with all bars 304, 305, 306 308 illuminated or activated while FIG. 3D shows poor signal strength, having only the first bar 304 and second bar 305 illuminated, and the third bar 306 and fourth bar 308 not illuminated. Both FIGS. 3A and 3D, however, indicate the same congestion level (“minimal”). FIGS. 3A, 3B, and 3C all show displays with excellent signal strength, having all bars 304, 305, 306, 308 illuminated. FIGS. 3D, 3E, and 3F all show displays with poor signal strength, having only the first bar 304 and second bar 305 illuminated. FIGS. 3B and 3E show a congestion indicator 310 having cross-hatching with wavy lines (indicating some or average congestion). FIGS. 3C and 3F both show a congestion indicator 310 having “X” cross-hatching, indicating high congestion. Thus, FIG. 3A has the best overall signal characteristics, signal strength (excellent) and congestion level (minimal), while FIG. 3F has the worst overall signal characteristics, signal strength (poor) and congestion level (high) as shown by the signal strength and congestion indicators 302. Other varying levels of the overall signal characteristics are shown in FIGS. 3B-3E. A user can thus easily evaluate an access point environment and quickly determine how to remedy any connection problems by having both signal strength and congestion information provided in one display. The additional feedback of congestion information therefore allows a user to make more informed decisions regarding the wireless environment in which the user is operating.

The determination as to the congestion level of the wireless environment of any particular node may be accomplished in a wide range of manners and the concepts of the present disclosure in a broadest sense are not limited to any particular method of determining the congestion level.

One approach for determining the congestion level of a wireless network is the known approach of Gupta and Kumar (from P. Gupta and P. R. Kumar, “The Capacity of Wireless Networks,” IEEE Trans. Inform. Theory 46[2]: 388-404, March 2000). Per Gupta and Kumar, every node all over the domain needs to share whatever portion of the channel it is utilizing with nodes in its local neighborhood, which causes constriction in capacity. Splitting the channel into several sub-channels will not change any of the results. In this approach, the number of nodes and the transmission capabilities of each node are related to obtain a theoretical throughput of each node. With the addition of a factor for correlating the theoretical throughput to an actual throughput, the congestion level determination of Gupta and Kumar may be shown by the equation:

$$B = \frac{β W}{\sqrt{n log n}} \qquad Eq . 1$$

Where “n” is the number of identical randomly located nodes, each capable of transmitting at “W” bits/sec, “β” is a correlation factor that correlates the theoretical Gupta Kumar equation to the empirically measured environment of a particular network and “B” is the overall throughput obtained by each node which in this one illustrative embodiment may be correlate to the congestion level as described herein. The correlation factor “β” may be utilized where the network environment is known and fixed such that it may be empirically studied (for example, an office environment). Such a correlation may thus accommodate real world environments that may effect the theoretical assumptions, such reflections and deflections, outside interference, etc. Alternatively, the correlation factor “β” need not be utilized. Further, as mentioned above, the concepts disclosed herein are not limited to any particular method of identifying the congestion level of the wireless environment in which a node exists and the Gupta Kumar based approach is shown merely for illustrative purposes.

Utilizing the Gupta Kumar based approach described above for determining the congestion of the wireless network includes utilizing the number of surrounding nodes utilizing the wireless network. In one embodiment, this may be obtained by placing the wireless resources of a node (such as node 102A) in a sniffing mode or “promiscuous” mode. In such a mode, the node detects the number of surrounding nodes in the wireless environment. By counting the number of nodes transmitting in the given wireless network congestion information based upon the wireless capacity of node may be obtained. In a more basic technique, the congestion may be determined merely upon the raw number of other nodes present.

Many sniffing techniques are well known in the art and the concepts described herein are not limited to any particular sniffing technique. In one sniffing approach, the characteristics of the well known OSI 7 layer network protocol are utilized. In the OSI 7 layer protocol, the overall protocol is divided into seven layers, the application layer, presentation/syntax layer, session layer, transport layer (for example TCP), network layer (for example IP), data link layer (for example MAC) and physical layer. Each wireless transmission will thus include information related to the data link layer. More particularly for most standards, such information typically includes in the data link layer the sending and receiving MAC address for each transmission (the MAC or media access control address being a hardware address that generally uniquely identifies each node of a network). Though the sniffing of MAC addresses is described herein, sniffing of other data may similarly be utilized to determine the congestion level of a particular network. Further, as mentioned above, the concepts described herein need not be limited to sniffing as other congestion identification techniques may be utilized.

By sniffing the packets being transmitted by the various nodes and/or access points of a wireless environment, the number of surrounding nodes may then be identified by monitoring the number of unique MAC addresses detected in the environment. The identification and counting of the surrounding nodes may be achieved in one embodiment by sniffing for transmissions from surrounding nodes to an access point. Thus, for example with reference to FIG. 1, node 102A may sniff for transmissions to the access point 104 and identify the presence of surround nodes 102B and 102C by identifying the sending MAC addresses contained in the transmissions to the access point 104. It will be noted that such sniffing may not detect all nodes connected to an access point 104 such as shown in FIG. 1 since hidden node 108 may be outside of the sensing range 106 of the node 102A. If the identification of node 108 is also desired, the sniffing may be configured so as to sniff the transmissions from the access point rather than transmissions to the access point. In addition, the sniffing may be configured in an “ad hoc” mode in which all transmissions present in the wireless environment are sniffed, irrespective of the type of node the transmissions originate from (i.e. sniffing access point nodes and non-access point nodes). As each transmission typically includes both a sending and receiving MAC address, counting the number of receiving MAC addresses included in the transmissions from the access point may be used as a technique for detecting all nodes communicating with the access point. In one embodiment, the sniffing techniques may be utilized over some period of time so as to give a more accurate gauge of the number of nodes utilizing an access point. For example, the number of numbers may be identified based upon the number of nodes utilized in a 5 minute period of time, 10 minute period of time, or a 30 minute period of time, etc. As sniffing techniques typical consume system resources of the sniffing node (processor cycles, power, etc.), the sniffing may be configured to sniff only at discrete intervals within the given time period and then an average value for the time period may be estimated. It will be recognized that a wide range of sniffing techniques may be utilized. In this manner, the number of nodes utilizing an access point may be identified and such information may then be utilized to determine the limitations on a particular nodes throughput caused by the amount of surrounding congestion.

As described above, the sniffing techniques were utilized to determine the number of surrounding nodes in the wireless environment. However, it will be recognized that such techniques could also be used to provide a more detailed quantitative analysis of the actual bandwidth usage of the surrounding nodes. For example, the amount and size of the transmissions to or from the surrounding nodes may monitored to provide a more detailed analysis of the congestion level that may include bandwidth usage. A combination of these or many other techniques may be utilized to establish the congestion level.

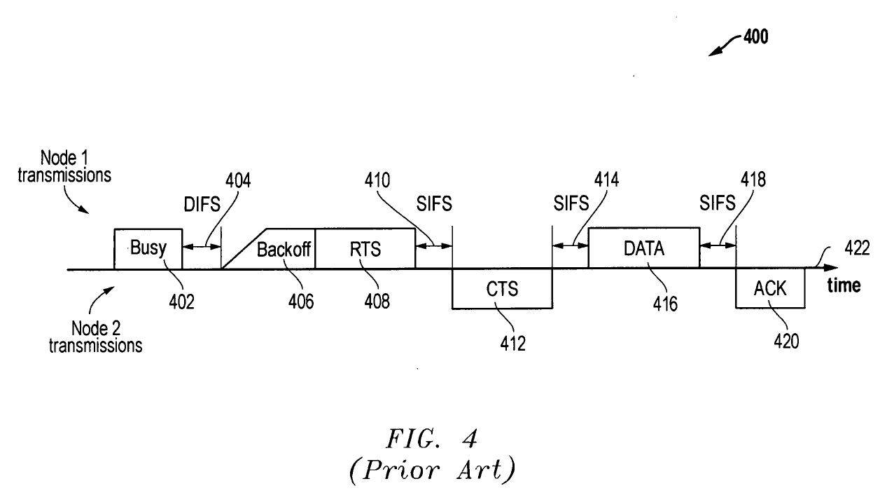

As described above, in one embodiment the MAC addresses contained in transmissions to or from the access point may be sniffed. An exemplary standard that provides such MAC addresses is shown in FIG. 4 for illustrative purposes only as the concepts described herein are not limited to any particular wireless communication standard. FIG. 4 shows an IEEE 802.11 MAC RTS/CTS transmission 400. Using the techniques described herein, the amount of nearby nodes is determined by looking at the intricacies of the 802.11 Distributed Coordination Function—Media Access Control (DCF MAC) protocol. The IEEE 802.11 DCF MAC is primarily responsible for maintaining the network allocation vector (NAV), and requesting medium access. Channel medium reservation is implemented through the Request to Send/Clear to Send (RTS/CTS) message exchange with Carrier Sense Multiple Access/Collision Avoidance (CSMA/CA). A detailed two node transmission sequence is shown in FIG. 4. The RTS/CTS exchange is an optional part of IEEE 802.11 Distributed Coordinate Function (DCF), but is typically used in congested environments. By listening to the RTS packets 408 and determining the number of nodes requesting for transmission in a given period of time at the link layer via distinct MAC addresses, one can determine the number of nodes in a neighborhood. Alternatively, the CTS packets 416 sent by the access point may be monitored to detect the MAC addresses to which data is being sent. In addition, if RTS/CTS packets are not utilized, the DATA packet 416 and/or ACK packet 420 may also be monitored, however, monitoring such packets may consume more system resources.

Thus, the techniques described herein give a user an accurate gage of the user's transmission quality, including both congestion and signal strength information. By decoupling congestion/utilization from link strength, the user can better evaluate expected network service level and bandwidth. The user may thus make an informed decision about whether to associate with another wireless access point or whether to maintain a connection with a particular access point. The display mechanism distinguishes error losses (weak signals) from congestion losses (too much channel traffic). Thus, a user knows whether the environment is a weak signal area or a congested traffic channel. For security may be improved by making it easier for the user to detect wireless network attacks and isolate problematic channels (for example by detected suspicious flooding of the wireless environment with transmissions from one node). Decoupling link speed from congestion control is displayed, as in one example in FIGS. 3A-3F. Link speed or signal strength is shown by a number of bars 304, 305, 306, 308, as in the prior art. A four bar indication represents excellent signal strength, while a two bar indication represents poor signal strength. To display congestion, the bars could be colored red, yellow, and green. Red could indicate a congested channel, as in FIGS. 3C and 3F. Yellow could indicate average congestion, as in FIGS. 3B and 3E. Green could indicate minimal or no congestion, as in FIGS. 3A and 3D. As mentioned above, a wide range of techniques may be used to illustrate the strength and congestion information to a user. In one embodiment described herein the information is conveniently displayed in one graphical icon. However, the information may alternatively be displayed in two icons. In yet another embodiment the information may be displayed as a combination of an icon graphic and a alphanumerical message (for example text messages such as “crowded” and the like may describe the congestion level), and yet in another alternative both the signal strength and congestion information may be provided to a user as alphanumerical based information. This it will be recognized that a number of techniques may be utilized to provide the signal strength and congestion information in a display window for use by a user.

It will be recognized that the nodes described herein may be any type of information handling system. For example, any wireless device could display the signal strength and congestion data according to the techniques described herein. In one example the techniques may be useful for portable computing systems such as laptops or notebooks, in another example the techniques could be utilized in a wireless telephone environment such as a cellular telephone environment, other illustrative examples include PDAs and any other wireless device. Further, by reference to an access point herein the concepts are not meant to be limited to any particular network connection mechanism. For example such an access point may be a mechanism that is solely a wireless access device or alternatively a wide range of other devices used to connect a wireless node to a node. For example, the access point may be a switch, router, repeater, another wireless node, any other device used to couple a wireless node to a network, etc.

Further modifications and alternative embodiments of this invention will be apparent to those skilled in the art in view of this description. It will be recognized, therefore, that the present invention is not limited by these example arrangements. Accordingly, this description is to be construed as illustrative only and is for the purpose of teaching those skilled in the art the manner of carrying out the invention. It is to be understood that the forms of the invention herein shown and described are to be taken as the presently preferred embodiments. Various changes may be made in the implementations and architectures. For example, equivalent elements may be substituted for those illustrated and described herein, and certain features of the invention may be utilized independently of the use of other features, all as would be apparent to one skilled in the art after having the benefit of this description of the invention.

What is claimed is:

1. A method of providing signal strength information and congestion information related to use of an access point by a first node, comprising:
detecting the usage of the access point wireless environment by other nodes in order to obtain congestion information related to the access point;
detecting wireless network signal strength information at the first node; and
displaying, at the first node, the signal strength information and the congestion information.

2. The method of claim 1, wherein the usage is the amount of other nodes connecting to the access point.

3. The method of claim 1, wherein the usage is the amount of bandwidth consumed by other nodes connecting to the access point.

4. The method of claim 1, further comprising allowing a user to select an access point based on the information provided.

5. The method of claim 1, wherein the usage includes the amount of bandwidth utilized by other nodes connecting to the access point.

6. The method of claim 1, wherein the signal strength and congestion information is displayed graphically.

7. The method of claim 6, wherein the signal strength and congestion information is displayed in a common graphical illustration.

8. The method of claim 7, wherein signal strength information is displayed via bars on the graphical illustration.

9. The method of claim 7, wherein congestion information is displayed via a color on the graphical illustration.

10. A method of providing signal strength information and congestion information related to use of an access point by a first node, comprising:
detecting an amount of other nodes connected to an access point in an area as part of determining a wireless network congestion level;
determining a signal strength at the first node; and
graphically displaying, at the first node, the signal strength and the congestion level.

11. The method of claim 10, wherein the graphically displaying comprises using a common graphical illustration for displaying both the signal strength and the congestion level.

12. The method of claim 11, wherein the congestion level is also affected by the amount of bandwidth utilized by other nodes connecting to the access point.

13. The method of claim 11, further comprising allowing a user to select an access point based on the graphical illustration.

14. The method of claim 11, wherein signal strength indicates signal to noise ratio.

15. The method of claim 11, wherein signal strength data is depicted with bars on the common graphical illustration.

16. The method of claim 11, wherein congestion data is depicted with color on the common graphical illustration.

17. The method of claim 16, wherein signal strength data is depicted with bars on the common graphical illustration.

18. An information handling system having a wireless signal strength and congestion data display related to use of an access point, comprising:
a wireless device within the information handling system configured to detect usage of the access point wireless environment by surrounding wireless nodes in order to obtain congestion information related to the access and to detect the wireless signal strength of the access point wireless environment;
a display window within the information handling system, the information handling system configured to provide signal strength and congestion data in the display window.

19. The information handling system of claim 18, wherein the congestion information is based at least in part by the number of surrounding nodes detected.

20. The information handling system of claim 18, wherein the congestion information is based at least in part by the detected bandwidth usage of the surrounding nodes.

21. The information handling system of claim 18, wherein the signal strength indicates signal to noise ratio.

22. The information handling system of claim 18, wherein the signal strength and congestion data is displayed graphically.

23. The information handling system of claim 22, wherein the signal strength and congestion data is displayed in a common graphical illustration.

24. The information handling system of claim 23, wherein signal strength is displayed via bars on the graphical illustration.

25. The information handling system of claim 24, wherein congestion data is displayed via a color on the graphical illustration.
